(19) United States
(12) Patent Application Publication
(10) Pub. No.: US 2004/0262555 A1
(43) Pub. Date: Dec. 30, 2004

(54) Apparatus, system and method of using a vibration beam with a piezo-electric actuator

(76) Inventors: Matthias Eisengruber, Nova Scotia (CA); Andre Veinotte, Ontario (CA)

Correspondence Address: MORGAN LEWIS & BOCKIUS LLP, 1111 PENNSYLVANIA AVENUE NW, WASHINGTON, DC, 20004, US

(21) Appl. No.: 10/732,800

(22) Filed: Dec. 11, 2003

Related U.S. Application Data
(60) Provisional application No. 60/432,533, filed on Dec. 11, 2002.

(51) Int. Cl. F16K 31/02; H02N 2/00; H01L 41/04

(52) U.S. Cl. 251/129.06; 310/323.02

(57) ABSTRACT

A system of providing movement along an axis. The system includes a beam, a piezo-electric actuator, and a plate. The beam includes a body that generally extends parallel to the axis between first and second ends. The beam also includes a plurality of arms that extend from the body to respective tips that are spaced from the body. The piezo-electric actuator is coupled to the beam and vibrates the beam so as to induce in the beam a wave between the first and second ends. And the plate is biased toward the body of the beam and contiguously engages the respective tips of the plurality of arms.

### CROSS REFERENCE TO RELATED APPLICATIONS

This application claims the benefit of the earlier filing date of U.S. Provisional Application No. 60/432,533, filed 11 Dec. 2002, which is incorporated by reference herein in its entirety.

### FIELD OF THE INVENTION

Piezo-electric actuators, which use one or more piezo ceramic cells, have been recently used in automotive applications, such as sensors and diesel common rail injection. The piezo-electric actuators have proven to be reliable and can be used in many applications. Piezo ceramics have the following general characteristics:

Exert high forces (kN range)

Very fast response time

Alternate at very high frequencies (kHz range)

Draw little current (mA range)

Use high Voltage (200V range)

Small displacement (μm range)

Traditional mechanical amplification methods fail to deliver a reasonable amplification factor of 100-200, which is necessary to deliver an approximately 6 millimeter stroke, such as would be useful for opening a typical exhaust gas recirculation (EGR) valve. It is believed that the traditional mechanical amplification methods are insufficient at least because of the tight manufacturing tolerances that are required for the mating components. Therefore, it is believed that there is a need to provide a different approach in order to achieve a travel of 6 millimeters or more. Further, in order to fully utilize the strength of a piezo-electric actuator, it makes sense to use the ability of piezo ceramics to alternate at high frequencies and to exert high forces.

### SUMMARY OF THE INVENTION

The present invention provides a system of providing movement along an axis. The system includes a beam, a piezo-electric actuator, and a plate. The beam includes a body that generally extends parallel to the axis between first and second ends. The beam also includes a plurality of arms that extend from the body to respective tips that are spaced from the body. The piezo-electric actuator is coupled to the beam and vibrates the beam so as to induce in the beam a wave between the first and second ends. And the plate is biased toward the body of the beam and contiguously engages the respective tips of the plurality of arms.

The present invention also provides an exhaust gas recirculation valve for controlling a flow of exhaust gas from an exhaust manifold of an internal combustion engine to an intake manifold of the internal combustion engine. The exhaust gas recirculation valve includes a passage, a pintle, a beam, a piezo-electric actuator, and a biasing element. The flow of exhaust gas is through the passage, which includes a seat that defines an aperture. The pintle moves along an axis between first and second configurations with respect to the seat. In the first configuration, the pintle occludes the aperture so as to prevent the flow of exhaust gas and, in the second configuration, the pintle is spaced from the seat so as to permit the flow of exhaust gas. The beam includes a body that extends generally parallel to the axis between first and second ends. The beam includes a plurality of arms that extend from the body to respective tips that are spaced from the body. The piezo-electric actuator is coupled to the beam and vibrates the beam so as to induce in the beam a wave between the first and second ends. And the biasing element couples the beam to the pintle.

The present invention also provides a vibration beam that includes a body, a plurality of arms, and a piezo-electric actuator. The body extends generally parallel to a first axis between first and second ends. The plurality of arms extend from the body to respective tips that are spaced from the body. The piezo-electric actuator expands and contracting along a second axis in response to an electric signal being supplied to the piezo-electric actuator, the piezo-electric actuator inducing in the body a wave between the first and second ends.

### BRIEF DESCRIPTION OF THE DRAWINGS

The accompanying drawings, which are incorporated herein and constitute part of this specification, illustrate presently preferred embodiments of the invention, and, together with the general description given above and the detailed description given below, serve to explain features of the invention.

FIG. 1 is a schematic illustration of a first condition of a movement system in accordance with the detailed description of a preferred embodiment.

FIG. 2 is a schematic illustration of a second condition of the movement system shown in FIG. 1.

FIG. 3 is a schematic illustration of a third condition of the movement system shown in FIG. 1.

FIG. 4 is a schematic illustration of a fourth condition of the movement system shown in FIG. 1.

FIG. 5 is a schematic illustration of an alternate movement system in accordance with the detailed description of a preferred embodiment.

FIGS. 6A and 6B illustrate an effect of changing a drive frequency of a movement system in accordance with the detailed description of a preferred embodiment.

FIG. 7 shows a perspective view of a vibration beam in accordance with a first preferred embodiment.

FIG. 8 shows a perspective view of a vibration beam in accordance with a second preferred embodiment.

FIG. 9 is a chart of different modes of the vibration beam shown in FIG. 7.

FIG. 10 is an electrical schematic of a vibration beam driver circuit in accordance with the detailed description of a preferred embodiment.

### DETAILED DESCRIPTION OF THE PREFERRED EMBODIMENT

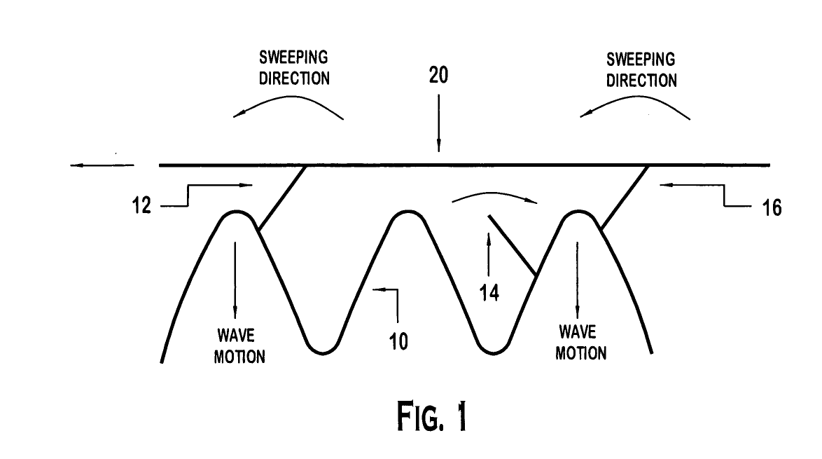

A beam 10 forced at its harmonic frequency will be excited into a standing wave. As seen in FIG. 1, if the beam 10 is connected to a so-called friction plate 20, the motion of the harmonic wave can cause the friction plate 20 to move in one direction. Note, the friction plate 20 is always pressed against the beam 10 ensuring constant contact. Strategically placed teeth 12,14,16 along the vibration beam 10 allow for control of the direction of motion of the friction plate 20 as well as optimizing the magnitude of movement. At least three, ideally 4 teeth are necessary to convert the standing wave motion into movement in one direction. Two teeth 12,16 have to be positioned slightly to one side of the crests of the wave, the third tooth 14 has to be at the node of the wave. The time sequence shown in FIGS. 1-4 clarifies the principle.

In FIG. 1, at t=t₀, the friction plate 20 is sitting high centered on top of the teeth 12,16. The wave is moving down and therefore the trajectory of the tip of the teeth 12,16 is moving to the left. The beam 10 will follow the motion of the teeth 12,14,16. Note, the tooth 14 is not touching the friction plate 20 at this point and its trajectory is moving the opposite direction of the teeth 12,16.

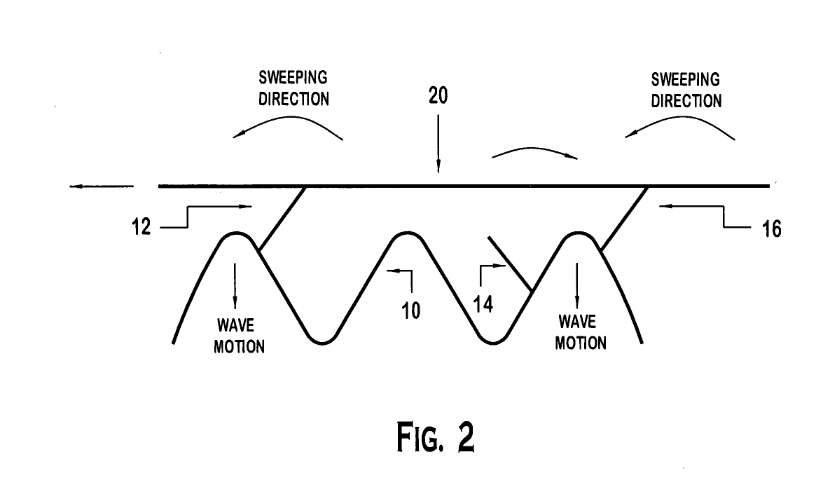

In FIG. 2, at t=t₁, the teeth 12,16 are following the motion of the wave. Even though the wave is going down, the teeth 12,16 are still the highest point on the beam 10. At this point the tooth sweeping motion is clearly visible. The friction plate 20 continues to move to the left.

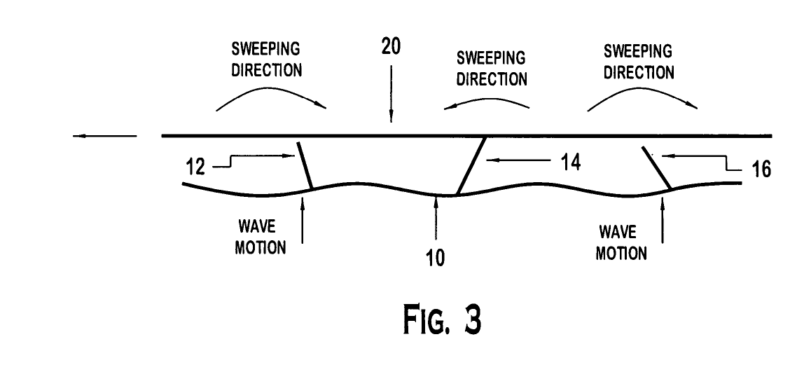

In FIG. 3, at t=t₂, all the teeth are at the same height. The teeth 12,16 continue to fall and also change sweeping direction. At this point the tooth 14 becomes the highest point on the beam 10 supporting the friction plate 20. Note that at this point the tooth 14 has changed sweeping direction, now sweeping to the left. This continues to move the friction plate 20 to the left.

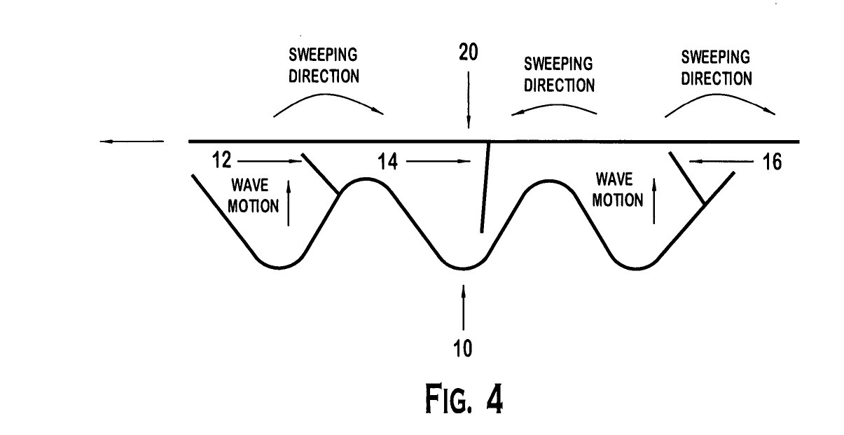

FIG. 4, at t=t₃, is almost the same as FIG. 2. The only difference being that now the tooth 14 is transporting the beam to the left and the teeth 12,16 are not touching the friction plate 20.

The cycle continues from here on. Basically the teeth 12,6 switch with the tooth 14 whenever they change sweeping motion. This kind of motion can be compared to a centipede found in nature.

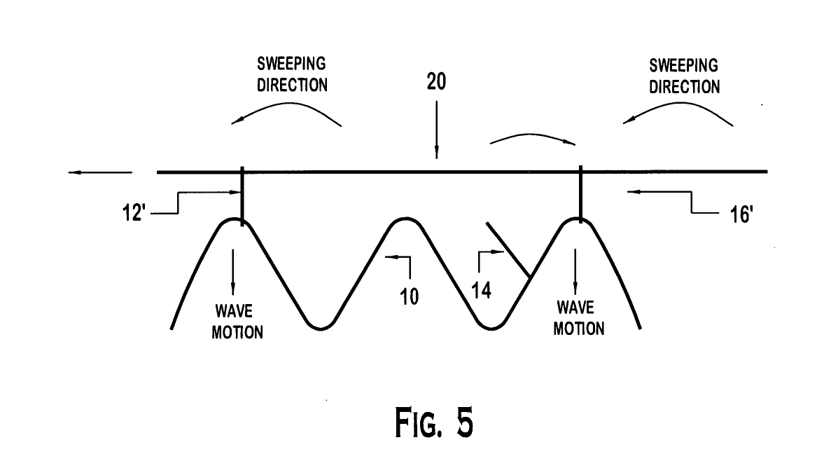

Another less efficient method can be used that operates according to the principle explained above. FIG. 5 shows teeth 12′,16′ exactly on top of the crest.

This method is less efficient but easier to manufacture since teeth 12′,16′ are exactly on the crest. The teeth 12′,16′ will not sweep as in described earlier, they will only move up and down. Only the tooth 14 provides the sweeping motion in this case.

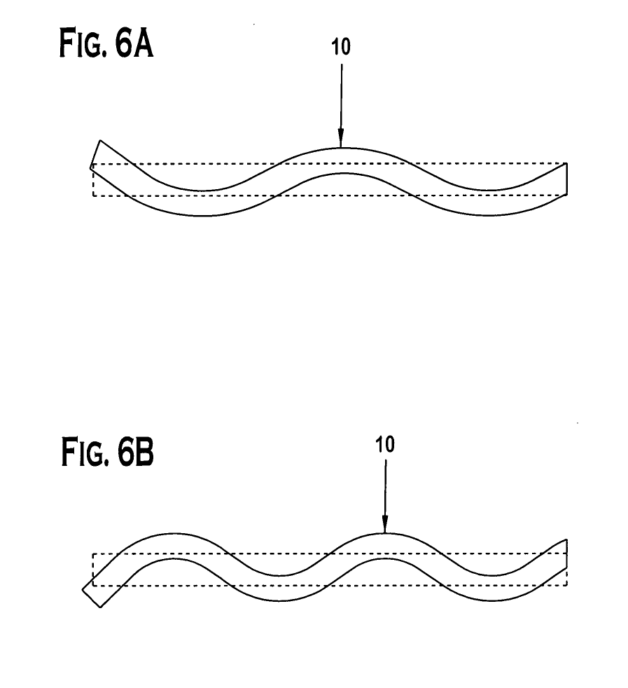

In order to move the friction plate 20 the other direction, all that has to be adjusted is the frequency of the wave. If the frequency is doubled, therefore half the wavelength, the teeth 12,16 are on the other side of the crest. If the beam 10 is driven at this faster frequency, the same movement phenomenon occurs as described above. However in this case the plate 20 will move to the right. Hence controlling the frequency means controlling the direction of movement. Referring additionally to FIGS. 6A and 6B, in comparing two wave lengths f₁=2f₂, the teeth will be sitting on the other side of the crest in each case resulting in controlled motion.

At least two methods of inducing a standing wave into a beam 10 will now be discussed. Buckling a beam by exerting a force at either end 10A,10B of the beam 10 or a simply supported beam 10 with a perpendicular force causing the bending of the beam 10. For the purposes of the following discussion, the second method was chosen, since the placement of the supports provides control of the wavelength and therefore the length of the beam 10. The two ends 10A,10B of a simply supported beam 10 are fixed, making them two nodes of the wave.

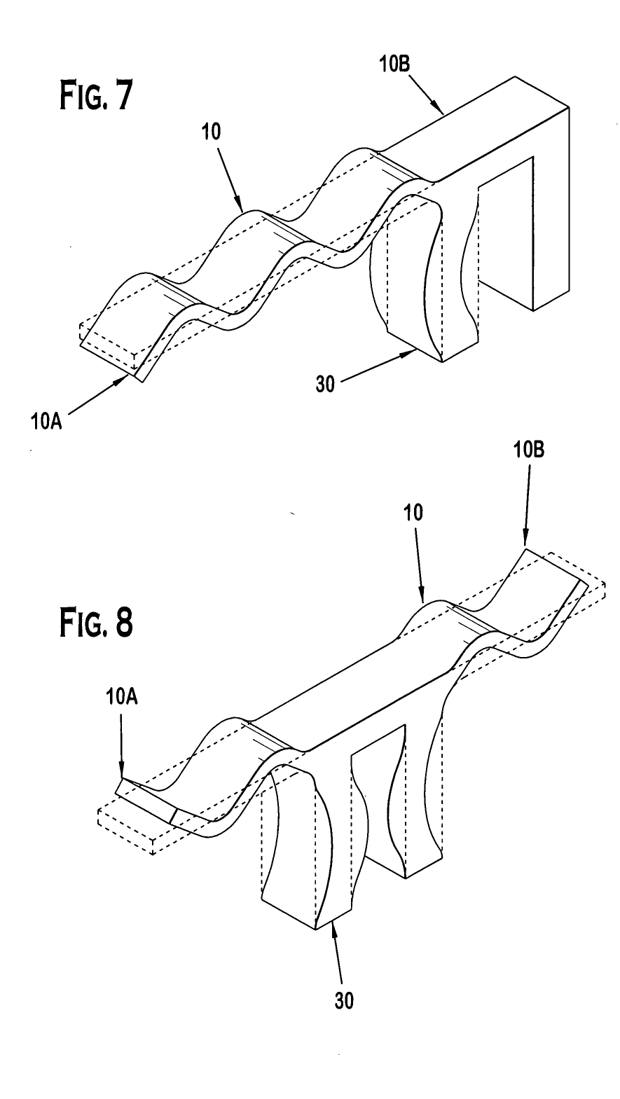

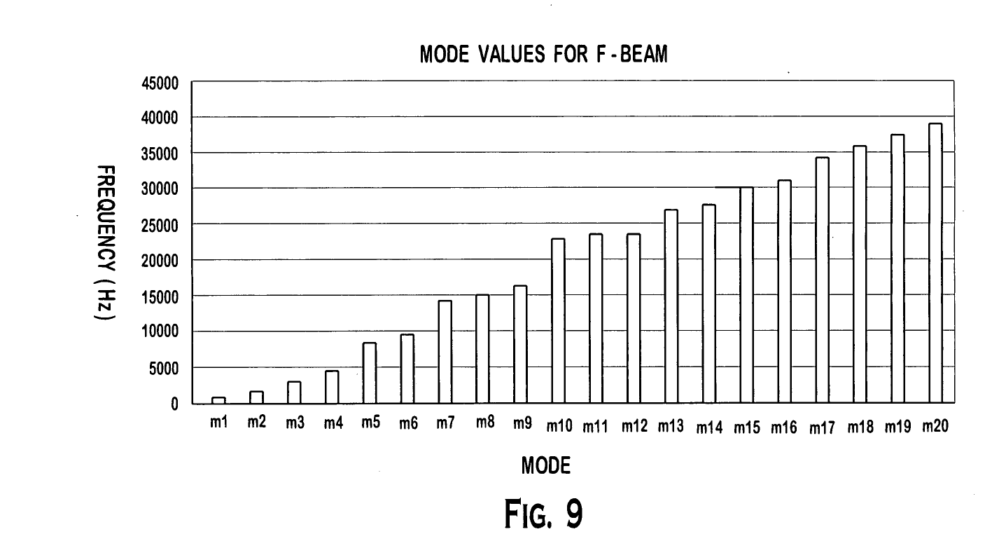

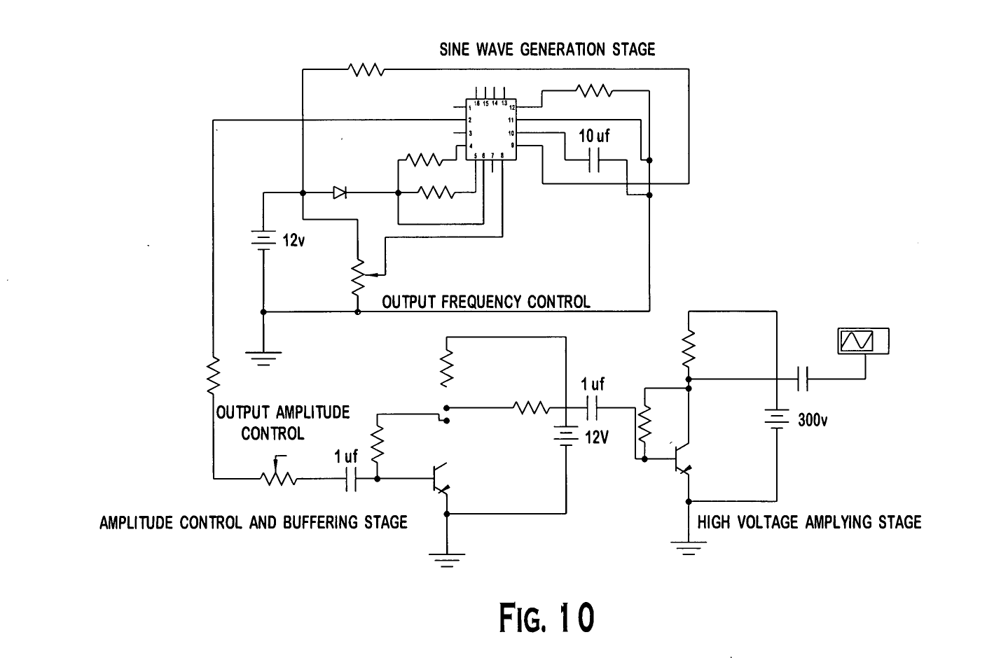

This in combination with accommodating a piezo-electric actuator 30 led to different beam designs, including the so-called F and T beams as shown in FIGS. 7 and 8, respectively. The length of the beam 10 could be kept to a minimum by keeping the supports as close together as possible still allowing enough space for the piezo-electric actuator 30 in between. The force exerted by the piezo-electric actuator 30 also provided minimum dimensions of the beam 10 in order to prevent yielding and shearing the beam 10. An advantage of the T beam was discovered to be the elimination of the bending moment at the base of the beam 10 that exists with the F beam. Modeling both beams in finite element analysis showed that the F beam had several advantages, including wave characteristics that are superior to the T beam. The T beam needs to be twice as long as the F beam in order to generate a similar waveform. Thus, a good waveform could be achieved even if the bending moment could not be completely eliminated. For the purposes of this application, the F beam will be discussed hereinafter.

An EGR valve is a common component in today's automobiles to reduce emissions and increase the efficiency of the engine by lowering the combustion temperature of the engine. A lower combustion temperature prevents the formation of NOX's reducing the emission levels of the vehicle.

Traditionally a valve, flap or pintle connected to an actuator regulates the amount of exhaust gas going into the engine. Prior art used so far are stepper motors, solenoid coils combined with armatures, DC motors and vacuum actuators. These actuators have been available for years and are approaching their maximum level of optimization.

In the case of the EGR, the pintle would be the friction plate 20. Since a relatively high force is required to open a pintle, it is necessary to have a high normal force between the friction plate 20 and the tip of the teeth 12,14,16. The higher the normal force, the better the teeth will grip into the friction plate and move it with a higher force. In order to guarantee a successful bending of the beam 10, a high force monolithic multi-layer piezo-electric actuator 30 may be used. Examples of two piezo-electric actuator 30 are illustrated in the following table, which shows the technical data for each one:

| Dimen- | Dimen- | Dimen- | Elonga- | Max | | Max |
|---|---|---|---|---|---|---|
| sion | sion | sion | tion | Force | Capacitance | Frequency |
| a (mm) | b (mm) | L (mm) | S (um) | F (N) | C (nF) | f (kHz) |
| 6.0 | 5.1 | 30 | 35 | 950 | 1700 | 40 |
| 11 | 10.1 | 30 | 35 | 4000 | 7000 | 40 |

The following advantages of the EGR valve according to the present invention can be foreseen compared to other art:

| | Vacuum | | | |
|---|---|---|---|---|
| | EGR | Stepper EGR | Electric EGR | Piezo EGR |
| Speed | Slow | Fast | Fast | Fast |
| Force | Medium | High | Medium-High | High |
| Accuracy | Marginal | Good | Good | Good |
| Costs | Low | Medium | Medium | Medium-High |

Although the costs of the piezo EGR valve are medium to high compared to other actuators, it is believed that with increasing volume of piezo-electric actuators, the price per unit will drop significantly.

One example of a piezo EGR valve according to the present invention may have a beam 10 that includes an F beam, an F beam mounting plate, a block force insert and the piezo-electric actuator 30. The F beam mounting plate provides the base for the beam 10. The block force insert is sitting in a cavity in the insert. The F beam is bolted to the mounting plate and the piezo-electric actuator 30 is wedged in between the block force insert and F beam. Each piezo-electric actuator 30 needs to be pre-stressed with half the force that it can exert to prevent destruction of the piezo-electric actuator 30. Preferably, the piezo-electric actuator 30 needs to be pre-loaded with at least 2 kilo-Newtons. This is achieved by turning an adjustment screw in the mounting plate, which shortens the space for the piezo-electric actuator 30 that is available between the insert and F beam. Without this blocking force the piezo will expand faster than the internal components of the piezo-electric actuator 30 can handle. For an EGR valve, more than one, e.g., three, F beam assemblies may be used. Each assembly is held in place by a housing hex housing and the adjustment screw. Spring may also be placed in between the adjustment screw and F beam assembly. Such a spring, which can also be a rubber insert, is necessary to provide a normal force acting against a triangular shaped pintle. By threading the holes in the housing and the adjustment screw, it is possible to adjust the magnitude of the normal force.

As indicated in FIG. 9, most of the useable wave modes are close to or in the ultrasonic range. This should make operating an EGR valve very quiet, as the operating range is ultrasonic.

While the present invention has been disclosed with reference to certain preferred embodiments, numerous modifications, alterations, and changes to the described embodiments are possible without departing from the sphere and scope of the present invention, as defined in the appended claims. Accordingly, it is intended that the present invention not be limited to the described embodiments, but that it have the full scope defined by the language of the following claims, and equivalents thereof.

What is claimed is:

1. A system of providing movement along an axis, the system comprising:
a beam including a body extending generally parallel to the axis between first and second ends, the beam including a plurality of arms extending from the body to respective tips spaced from the body;
a piezo-electric actuator coupled to the beam, the piezo-electric actuator vibrating the beam so as to induce in the beam a wave between the first and second ends; and
a plate being biased toward the body of the beam and engaging contiguously the respective tips of the plurality of arms.

2. The system according to claim 1, wherein the plurality of arms comprises first and second sets of arms, the first set of arms includes a respective first set of tips and the second set of arms includes a respective second set of tips; and
wherein the first and second sets of tips alternatingly contiguously engage the plate to move the plate along the axis.

3. The system according to claim 2, wherein the piezo-electric actuator vibrates the beam at first and second frequencies, the first frequency moving the plate in a first direction along the axis and the second frequency moving the plate in a second direction along the axis, the second direction being opposite to the first direction.

4. The system according to claim 1, wherein each of the plurality of arms extends a length between the body and the respective tip, the length and a magnitude of the wave amplifying a displacement of the piezo-electric actuator.

5. The system according to claim 1, wherein each of the respective tips moves in a sweeping action in response to the piezo-electric actuator vibrating the beam.

6. The system according to claim 1, wherein the beam has a harmonic frequency and the piezo-electric actuator vibrates the beam at the harmonic frequency.

7. The system according to claim 1, further comprising:
a biasing element pressing the plate against the beam.

8. An exhaust gas recirculation valve controlling a flow of exhaust gas from an exhaust manifold of an internal combustion engine to an intake manifold of the internal combustion engine, the exhaust gas recirculation valve comprising:
a passage through which the flow of exhaust gas occurs, the passage including a seat defining an aperture;
a pintle movable along an axis between first and second configurations with respect to the seat, in the first configuration the pintle occludes the aperture so as to prevent the flow of exhaust gas, and in the second configuration the pintle being spaced from the seat so as to permit the flow of exhaust gas;
a beam including a body extending generally parallel to the axis between first and second ends, the beam including a plurality of arms extending from the body to respective tips spaced from the body;
a piezo-electric actuator coupled to the beam, the piezo-electric actuator vibrating the beam so as to induce in the beam a wave between the first and second ends; and
a biasing element coupling the beam to the pintle.

9. The exhaust gas recirculation valve according to claim 8, wherein the biasing element presses the beam and the pintle into relative contiguous engagement.

10. The exhaust gas recirculation valve according to claim 8, wherein the piezo-electric actuator vibrates the beam at first and second frequencies, the first frequency moving the pintle toward the first configuration and the second frequency moving the pintle toward the second configuration.

11. A vibration beam comprising:
a body extending generally parallel to a first axis between first and second ends;
a plurality of arms extending from the body to respective tips spaced from the body; and
a piezo-electric actuator expanding and contracting along a second axis in response to an electric signal being supplied to the piezo-electric actuator, the piezo-electric actuator inducing in the body a wave between the first and second ends and inducing a sweeping motion of the respective tips.

12. The vibration beam according to claim 11, wherein the second axis is perpendicular to the first axis.

13. The vibration beam according to claim 11, wherein the first and second ends of the body are relatively fixed.

14. The vibration beam according to claim 13, wherein the body has a midpoint substantially half way between the first and second ends of the body.

15. The vibration beam according to claim 14, wherein the piezo-electric actuator is coupled to the body at the midpoint.

16. The vibration beam according to claim 14, wherein the piezo-electric actuator is coupled to the body at a point that is spaced a first distance from the first end and that is spaced a second distance from the midpoint, and the second distance is greater than the first distance.
